(19) United States
(12) Patent Application Publication
(10) Pub. No.: US 2026/0198387 A1
(43) Pub. Date: Jul. 9, 2026

(54) STACKED PACKAGE STRUCTURE AND METHOD FOR FORMING THE SAME

(71) Applicant: JCET Microelectronics (Jiangyin) Co., LTD., Jiangyin (CN)

(72) Inventor: Cheng YANG, Jiangyin (CN)

(73) Assignee: JCET Microelectronics (Jiangyin) Co., LTD., Jiangyin (CN)

(21) Appl. No.: 19/439,419

(22) Filed: Jan. 4, 2026

(30) Foreign Application Priority Data
Jan. 9, 2025 (CN) 202510036194.9

(51) Int. Cl. H10W 90/00; H05K 1/189; H10B 80/00; H10D 80/30; H10W 70/60; H10W 90/10; H10W 90/20; H10W 90/26

(52) U.S. Cl. CPC H10W 90/401; H05K 1/189; H10W 70/611; H10W 90/10; H10W 90/26; H10W 90/297; H10W 90/725; H10W 90/7295; H10W 90/735; H10B 80/00; H10D 80/30; H10W 90/722; H10W 90/724; H10W 90/732; H10W 90/734

(57) ABSTRACT

A stacked package structure and a method for forming the same, are provided. The stacked package structure includes: a first substrate; a chip stacked structure on an upper surface of the first substrate, the chip stacked structure includes first semiconductor chips stacked in sequence along a direction perpendicular to the upper surface; a first functional surface of a first portion of a first flexible circuit board is mounted on a top surface of the chip stacked structure, and a second portion of the first flexible circuit board is bent to a side surface of the chip stacked structure; a part of a third functional surface of a second flexible circuit board is mounted on a second functional surface of the second portion of the first flexible circuit board; and second semiconductor chips are mounted on a fourth functional surface of the second flexible circuit board.

### CROSS-REFERENCE TO RELATED APPLICATIONS

This application claims the benefit of priority to Chinese Application No. 202510036194.9, filed Jan. 9, 2025, which is incorporated herein by reference in its entirety.

### TECHNICAL FIELD

The present application relates to the field of semiconductor package, and particularly relates to a stacked package structure and a method for forming the same.

### BACKGROUND

As chip miniaturization becomes increasingly difficult while the market's pursuit of high-performance chips remains relentless, the industry has begun to explore breakthroughs in the package field, and in recent years, advanced chip package technologies such as 2.5D package technology, 3D package technology, etc., have become a focus of attention for foundries, package and testing factories, chip design manufacturers, and EDA manufacturers.

### SUMMARY

In one aspect, the embodiments of the present disclosure provide a stacked package structure, which includes: a stacked package structure, which includes: a first substrate, the first substrate includes opposed upper surface and lower surface; a chip stacked structure located on the upper surface of the first substrate, the chip stacked structure includes a plurality of first semiconductor chips stacked in sequence along a direction perpendicular to the upper surface of the first substrate, and the chip stacked structure is electrically connected with the first substrate; a first flexible circuit board, the first flexible circuit board includes opposed first functional surface and second functional surface, the first flexible circuit board further includes a first portion and at least one second portion connected with the first portion, the first functional surface of the first portion of the first flexible circuit board is mounted on the top surface of the chip stacked structure and is electrically connected with the chip stacked structure, and the second portion of the first flexible circuit board is bent to the side surface of the chip stacked structure; a second flexible circuit board, the second flexible circuit board includes opposed third functional surface and fourth functional surface, and a part of the third functional surface of the second flexible circuit board is mounted on the second functional surface of the second portion of the first flexible circuit board and is electrically connected with the first flexible circuit board; and second semiconductor chips mounted on the fourth functional surface of the second flexible circuit board and electrically connected with the second flexible circuit board.

In some embodiments, each first semiconductor chip in the chip stacked structure includes opposed first surface and second surface, and a first side surface located between the first surface and the second surface, and the first semiconductor chips have in them integrated circuits, and the first surface has a plurality of discrete first external terminals, and the second surface has a plurality of discrete second external terminals, and the first external terminals and second external terminals are electrically connected with the integrated circuits; when the plurality of first semiconductor chips are stacked in sequence along a direction perpendicular to the upper surface of the first substrate, the first surfaces of the first semiconductor chips in the upper-layer are stacked facing downward on the second surfaces of the first semiconductor chips in the lower-layer, and the first external terminals on the first surfaces of the first semiconductor chips in the upper-layer are electrically connected with the second external terminals on the second surfaces of the first semiconductor chips in the lower-layer; the first substrate has in it first lines, and the upper surface of the first substrate has a plurality of discrete first upper solder pads, and the lower surface of the first substrate has a plurality of discrete first lower solder pads, and the first upper solder pads and first lower solder pads are electrically connected with the first lines, the first external terminals on the first surfaces of the first semiconductor chips of the bottommost layer are electrically connected with the corresponding first upper solder pads on the upper surface of the first substrate.

In some embodiments, the first flexible circuit board has in it second lines; the first functional surfaces of the first portion and the second portion of the first flexible circuit board have a plurality of discrete first solder pads, the second functional surface of the second portion of the first flexible circuit board has a plurality of discrete second solder pads, and the first solder pads and the second solder pads are electrically connected with the first lines; and the second flexible circuit board has in it third lines, and the third functional surface of the second flexible circuit board has a plurality of discrete third solder pads, and the fourth functional surface of the second flexible circuit board has a plurality of discrete fourth solder pads, and the third solder pads and the fourth solder pads are electrically connected with the third lines.

In some embodiments, the first functional surface of the first portion of the first flexible circuit board being mounted on the top surface of the chip stacked structure and electrically connected with the chip stacked structure includes: the first solder pads on the first functional surface of the first portion of the first flexible circuit board are soldered together with the corresponding second external terminals on the second surfaces of the first semiconductor chips of the topmost layer in the chip stacked structure through first solder bumps; a part of the third functional surface of the second flexible circuit board being mounted on the second functional surface of the second portion of the first flexible circuit board and electrically connected with the first flexible circuit board includes: third solder pads on a part of the third functional surface of the second flexible circuit board are soldered together with corresponding second solder pads on the second functional surface of the second portion of the first flexible circuit board through second solder bumps; and the second semiconductor chips being mounted on the fourth functional surface of the second flexible circuit board and electrically connected with the second flexible circuit board includes: the second semiconductor chips are soldered together with the corresponding fourth solder pads on the fourth functional surface of the second flexible circuit board through third solder bumps.

In some embodiments, the second functional surface of the second portion of the first flexible circuit board is adhered to the side surface of the chip stacked structure.

In some embodiments, the second functional surface of the second portion of the first flexible circuit board is directly adhered to the side surface of the chip stacked structure through an adhesive layer.

In some embodiments, the stacked package structure further includes third semiconductor chips, the third semiconductor chips are mounted on the first functional surface of the second portion of the first flexible circuit board and are electrically connected with corresponding first solder pads on the first functional surface of the second portion through fourth solder bumps; the surfaces of the third semiconductor chips away from the first functional surface of the second portion of the first flexible circuit board are directly adhered to the side surface of the chip stacked structure through an adhesive layer.

In some embodiments, the second flexible circuit board is not electrically connected with the first substrate.

In some embodiments, the second flexible circuit board is electrically connected with the first substrate.

In some embodiments, the second flexible circuit board being electrically connected with the first substrate includes: a part of the second flexible circuit board is bent and extends parallel to a part of the upper surface of the first substrate, and the bent portion of the second flexible circuit board is soldered and electrically connected with corresponding first upper solder pads on the upper surface of the first substrate through connection solder balls.

In some embodiments, the second flexible circuit board being electrically connected with the first substrate includes: the second flexible circuit board and the first substrate are rigid-flex boards, and the second flexible circuit board is flexible and the first substrate is rigid, and the second flexible circuit board is partially embedded into the first substrate and electrically connected with the first substrate.

In some embodiments, the second flexible circuit board being electrically connected with the first substrate includes: the first substrate further includes a plurality of side surfaces located between the upper surface and the lower surface, and the second flexible circuit board extends from at least one side surface of the first substrate to the lower surface of the first substrate and is electrically connected with the first substrate from the lower surface of the first substrate.

In some embodiments, the second flexible circuit board being electrically connected with the first substrate includes: the first substrate is also a flexible board, the first substrate and the second flexible circuit board are a one-piece structure with an electrical connection, and the second flexible circuit board is bent upward from at least one side of the first substrate.

In some embodiments, the surfaces of the first lower solder pads on the lower surface of the first substrate have protruding first external solder bumps; the stacked package structure further includes: a second substrate, and the second substrate has in it fourth lines, and the upper surface of the second substrate has second upper solder pads, and the lower surface of the second substrate has second lower solder pads, and the second upper solder pads and second lower solder pads are electrically connected with the fourth lines; the first substrate is located on the second substrate, and the first external solder bumps on the lower surface of the first substrate are soldered together with the corresponding second upper solder pads on the upper surface of the second substrate; the surfaces of the second lower solder pads on the lower surface of the second substrate have protruding second external solder bumps.

In some embodiments, the number of the second portions in the first flexible circuit board is one or more; when there are a plurality of second portions, the plurality of second portions are respectively bent to different side surfaces of the chip stacked structure.

In some embodiments, the number of the second flexible circuit boards is one or more; when the number of the second flexible circuit boards is one, the one second flexible circuit board is electrically connected with one or more of the second portions of the first flexible circuit board; when the number of second flexible circuit boards is multiple, the multiple second flexible circuit boards are correspondingly electrically connected with the plurality of second portions of the first flexible circuit board, respectively.

In some embodiments, the number of the second semiconductor chips is one or more; when the number of the second semiconductor chips is multiple, the multiple second semiconductor chips are stacked in sequence along a direction parallel to the upper surface of the first substrate on the fourth functional surface of the second flexible circuit board, or the multiple second semiconductor chips are all mounted at different positions on the fourth functional surface of the second flexible circuit board.

In some embodiments, the second semiconductor chips include opposed third surface and fourth surface and a plurality of side surfaces between the third surface and the fourth surface, and the third surface has third external terminals, and the third external terminals on the third surfaces of the second semiconductor chips are electrically connected with the corresponding fourth solder pads on the fourth functional surface of the second flexible circuit board through third solder bumps; a side surface of the second semiconductor chips close to the upper surface of the first substrate has side solder pads, and the side solder pads are soldered together with the corresponding first upper solder pads on the upper surface of the first substrate through fifth solder bumps.

Another aspect of the embodiments of the present disclosure further provides a method for forming a stacked package structure, which includes: providing a first substrate, the first substrate includes opposed upper surface and lower surface; forming a chip stacked structure on the upper surface of the first substrate, the chip stacked structure includes a plurality of first semiconductor chips stacked in sequence along a direction perpendicular to the upper surface of the first substrate, and the chip stacked structure is electrically connected with the first substrate; providing a first flexible circuit board, the first flexible circuit board includes opposed first functional surface and second functional surface, and the first flexible circuit board includes a first portion and at least one second portion connected with the first portion, the first functional surface of the first portion of the first flexible circuit board is mounted on the top surface of the chip stacked structure and is electrically connected with the chip stacked structure, and the second portion of the first flexible circuit board is bent to the side surface of the chip stacked structure; providing a second flexible circuit board, the second flexible circuit board includes opposed third functional surface and fourth functional surface, and a part of the third functional surface of the second flexible circuit board is mounted on the second functional surface of the second portion of the first flexible circuit board and is electrically connected with the first flexible circuit board; and providing second semiconductor chips, the second semiconductor chips are mounted on the fourth functional surface of the second flexible circuit board and are electrically connected with the second flexible circuit board.

In some embodiments, each first semiconductor chip in the chip stacked structure includes opposed first surface and second surface, and a first side surface located between the first surface and the second surface, and the first semiconductor chips have in them integrated circuits, and the first surface has a plurality of discrete first external terminals, and the second surface has a plurality of discrete second external terminals, and the first external terminals and second external terminals are electrically connected with the integrated circuits; when the plurality of first semiconductor chips are stacked in sequence along a direction perpendicular to the upper surface of the first substrate, the first surfaces of the first semiconductor chips in the upper-layer are stacked facing downward on the second surfaces of the first semiconductor chips in the lower-layer, and the first external terminals on the first surfaces of the first semiconductor chips in the upper-layer are electrically connected with the second external terminals on the second surfaces of the first semiconductor chips in the lower-layer; the first substrate has in it first lines, and the upper surface of the first substrate has a plurality of discrete first upper solder pads, and the lower surface of the first substrate has a plurality of discrete first lower solder pads, and the first upper solder pads and first lower solder pads are electrically connected with the first lines, the first external terminals on the first surfaces of the first semiconductor chips of the bottommost layer are electrically connected with the corresponding first upper solder pads on the upper surface of the first substrate.

In some embodiments, the first flexible circuit board has in it second lines; the first functional surfaces of the first portion and the second portion of the first flexible circuit board have a plurality of discrete first solder pads, the second functional surface of the second portion of the first flexible circuit board has a plurality of discrete second solder pads, and the first solder pads and the second solder pads are electrically connected with the first lines; the second flexible circuit board has in it third lines, and the third functional surface of the second flexible circuit board has a plurality of discrete third solder pads, and the fourth functional surface of the second flexible circuit board has a plurality of discrete fourth solder pads, and the third solder pads and the fourth solder pads are electrically connected with the third lines; the first functional surface of the first portion of the first flexible circuit board being mounted on the top surface of the chip stacked structure and electrically connected with the chip stacked structure includes: the first solder pads on the first functional surface of the first portion of the first flexible circuit board are soldered together with the corresponding second external terminals on the second surfaces of the first semiconductor chips of the topmost layer in the chip stacked structure through first solder bumps; a part of the third functional surface of the second flexible circuit board being mounted on the second functional surface of the second portion of the first flexible circuit board and electrically connected with the first flexible circuit board includes: the third solder pads on a part of the third functional surface of the second flexible circuit board are soldered together with the corresponding second solder pads on the second functional surface of the second portion of the first flexible circuit board through second solder bumps; and the second semiconductor chips being mounted on the fourth functional surface of the second flexible circuit board and electrically connected with the second flexible circuit board includes: the second semiconductor chips are soldered together with the corresponding fourth solder pads on the fourth functional surface of the second flexible circuit board through third solder bumps.

In some embodiments, the formation method further includes: adhering the second functional surface of the second portion of the first flexible circuit board to the side surface of the chip stacked structure.

In some embodiments, the second functional surface of the second portion of the first flexible circuit board is directly adhered to the side surface of the chip stacked structure through an adhesive layer.

In some embodiments, the forming method further includes: providing third semiconductor chips, the third semiconductor chips are mounted on the first functional surface of the second portion of the first flexible circuit board and are electrically connected with the corresponding first solder pads on the first functional surface of the second portion through fourth solder bumps; the surfaces of the second semiconductor chips away from the first functional surface of the second portion of the first flexible circuit board are directly adhered to the side surface of the chip stacked structure through an adhesive layer.

### BRIEF DESCRIPTION OF THE DRAWINGS

In order to facilitate understanding and illustrating the features and advantages of the present disclosure, the components in the following accompanying drawings are not necessarily drawn to scale, and components having similar related characteristics or features may have the same or similar reference numerals.

FIG. 1 is a top view structural schematic diagram of a stacked package structure according to an embodiment of the present disclosure;

FIG. 2 is a cross-sectional structural schematic diagram of the stacked package structure obtained along cutting line AA1 in FIG. 1 according to an embodiment of the present disclosure;

FIG. 3 is a cross-sectional structural schematic diagram of the stacked package structure obtained along cutting line AA1 in FIG. 1 according to another embodiment of the present disclosure;

FIG. 4 is a cross-sectional structural schematic diagram of the stacked package structure obtained along cutting line AA1 in FIG. 1 according to yet another embodiment of the present disclosure;

FIG. 5 is a cross-sectional structural schematic diagram of the stacked package structure obtained along cutting line AA1 in FIG. 1 according to yet another embodiment of the present disclosure;

FIG. 6 is a cross-sectional structural schematic diagram of the stacked package structure obtained along cutting line AA1 in FIG. 1 according to yet another embodiment of the present disclosure;

FIG. 7 is a cross-sectional structural schematic diagram of the stacked package structure obtained along cutting line AA1 in FIG. 1 according to yet another embodiment of the present disclosure;

FIG. 8 is a cross-sectional structural schematic diagram of the stacked package structure obtained along cutting line AA1 in FIG. 1 according to yet another embodiment of the present disclosure; and

FIG. 9 is a cross-sectional structural schematic diagram of the stacked package structure obtained along cutting line AA1 in FIG. 1 according to yet another embodiment of the present disclosure.

### DETAILED DESCRIPTION

The implementations of the package structure and the method for forming the same provided by the present disclosure are described in detail below in conjunction with the accompanying drawings.

As chip miniaturization becomes increasingly difficult while the market's pursuit of high-performance chips remains relentless, the industry has begun to explore breakthroughs in the package field, and in recent years, advanced chip package technologies such as 2.5D package technology, 3D package technology, etc., have become a focus of attention for foundries, package and testing factories, chip design manufacturers, and EDA manufacturers.

2.5D package technology or 3D package technology is the process of stacking identical or different chips together to form a stacked package structure. The main advantages of 2.5D package technology and 3D package technology include: by sequentially stacking a plurality of chips together along a direction perpendicular to the surface of the substrate to form a chip stacked structure, the integration degree and performance of the chips is thus improved; the connections between a plurality of chips in the chip stacked structure are achieved through vertical connection instead of traditional planar connection methods, so that the total wiring length between the chips can be reduced to increase bandwidth and improve signal latency, and thus enhance the reliability and stability of the package structure.

In stacked package structures formed using 2.5D package technology or 3D package technology, in addition to forming a chip stacked structure on the substrate, other chips (such as control chips, CPU chips, or GPU chips) are also mounted on the surface of the substrate on one side or around the chip stacked structure to improve the performance of the stacked package structure; however, existing other chips are mounted with their active surfaces parallel to the surface of the substrate, which will occupy a large surface area of substrate when other chips are mounted, thereby limiting the number of chips mounted on the surface of the substrate and limiting further improvement of the functionality and performance of the package structure.

The advantages of the technical solution of the present disclosure lie in the following.

In embodiments of the stacked package structure and method for forming the same, the first functional surface of the first portion of the first flexible circuit board of the stacked package structure is mounted on the top surface of the chip stacked structure and is electrically connected with the chip stacked structure, and the second portion of the first flexible circuit board is bent to the side surface of the chip stacked structure; a part of the third functional surface of the second flexible circuit board is mounted on the second functional surface of the second portion of the first flexible circuit board and is electrically connected with the first flexible circuit board; and the second semiconductor chips are mounted on the fourth functional surface of the second flexible circuit board and are electrically connected with the second flexible circuit board. Since the first flexible circuit board, the second flexible circuit board, and the second semiconductor chips in the stacked package structure of the present disclosure have the aforementioned mounting positions, and the first functional surface and the second functional surface of the second portion of the first flexible circuit board are non-parallel to the upper surface of the first substrate, and the third functional surface and the fourth functional surface of the second flexible circuit board are non-parallel to the upper surface of the first substrate, and the functional surfaces of the second semiconductor chips are also non-parallel to the upper surface of the first substrate, the areas occupied by the first flexible circuit board, the second flexible circuit board, and the second semiconductor chips on the upper surface of the first substrate are smaller, so that more other chips or devices can be mounted on the upper surface of the first substrate, which further improves the functionality and performance of the package structure; moreover, the presence of the first flexible circuit board and the second flexible circuit board increases the connection pathways between the chip stacked structure and external substrates or devices, which, on the one hand, can increase bandwidth (the chip stacked structure not only can be directly electrically connected with the first substrate but also can be electrically connected with the first substrate and the second semiconductor chips and/or the subsequently introduced third semiconductor chips through the first flexible circuit board and the second flexible circuit board), and which, on the other hand, can achieve more functional expansion and performance improvement of the package structure while occupying a smaller area on the upper surface of the first substrate (e.g., a second semiconductor chip with specific functions can be mounted or a plurality of second semiconductor chips with the same or different functions can be mounted on the fourth functional surface of the second flexible circuit board, a third semiconductor chip with specific functions can be mounted or a plurality of third semiconductor chips with the same or different functions can be mounted on the first functional surface of the second portion of the first flexible circuit board).

In one aspect, the embodiments of the present disclosure provide a stacked package structure.

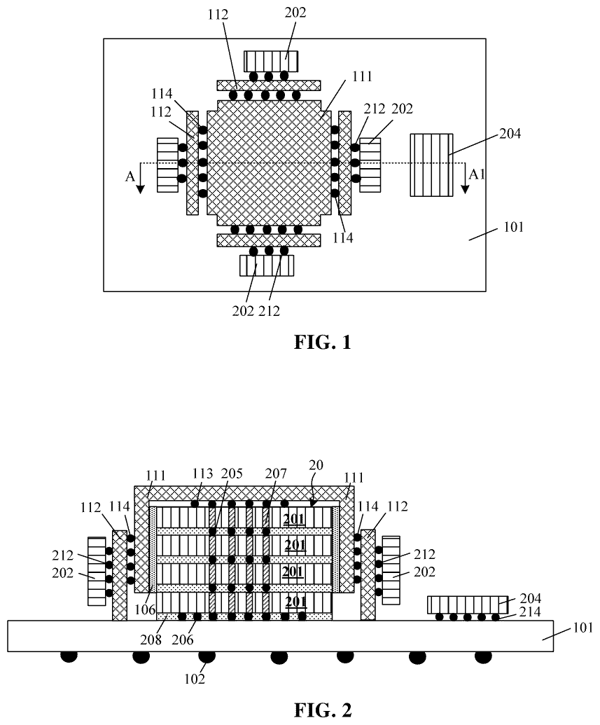

FIG. 1 is a top view structural schematic diagram of a stacked package structure according to an embodiment of the present disclosure; FIG. 2 is a cross-sectional structural schematic diagram of the stacked package structure obtained along cutting line AA1 in FIG. 1 according to an embodiment of the present disclosure.

Referring to FIGS. 1 and 2, the package structure includes: a first substrate 101, the first substrate 101 includes opposed upper surface and lower surface; a chip stacked structure 20 located on the upper surface of the first substrate 101, the chip stacked structure 20 includes a plurality of first semiconductor chips 201 stacked in sequence along a direction perpendicular to the upper surface of the first substrate 101, and the chip stacked structure 20 is electrically connected with the first substrate 101; a first flexible circuit board 111, the first flexible circuit board 111 includes opposed first functional surface and second functional surface, the first flexible circuit board 111 further includes a first portion and at least one second portion connected with the first portion, the first functional surface of the first portion of the first flexible circuit board 111 is mounted on the top surface of the chip stacked structure 20 and is electrically connected with the chip stacked structure 20, and the second portion of the first flexible circuit board 111 is bent to the side surface of the chip stacked structure 20; a second flexible circuit board 112, the second flexible circuit board 112 includes opposed third functional surface and fourth functional surface, and a part of the third functional surface of the second flexible circuit board 112 is mounted on the second functional surface of the second portion of the first flexible circuit board 111 and is electrically connected with the first flexible circuit board 111; and second semiconductor chips 202 mounted on the fourth functional surface of the second flexible circuit board 112 and electrically connected with the second flexible circuit board 112.

In some embodiments, the first substrate 101 in the stacked package structure serves as a support carrier and connection carrier during the package process. In one embodiment, the first substrate 101 may include opposed upper surface and lower surface, and the upper surface of the first substrate 101 has a plurality of discrete first upper solder pads (not shown in the figures), and the lower surface of the first substrate 101 has a plurality of discrete first lower solder pads (not shown in the figures), and the first substrate 101 has in it first lines (not shown in the figures), a part of the first lines may be used for electrical connections of the first upper solder pads on the upper surface of the first substrate 101 with the corresponding first lower solder pads on the lower surface of the first substrate 101, and a part of the first lines may also be used for electrical connection between a part of the first upper solder pads on the upper surface of the first substrate 101, and a part of the first lines may also be used for electrical connection between a part of the first lower solder pads on the lower surface of the first substrate 101. The first upper solder pads on the upper surface of the first substrate 101 may be electrically connected with the chip stacked structure or other devices mounted on the first substrate, and first external solder bumps 102 may be formed on the first lower solder pads on the lower surface of the first substrate 101, and the first external solder bumps 102 serve to be connected with other devices, other first substrates, or package structures. The materials of the first upper solder pads, the first lower solder pads, and the first lines are metal, which may be one or more of aluminum, copper, nickel, tin, titanium, tungsten, platinum, chromium, tantalum, gold, or silver. The material of the first external solder bumps 102 is tin or tin alloy, and the tin alloy is one or more of tin-silver, tin-zinc, tin-lead, tin-indium, tin-gold, tin-copper, tin-silver-copper, tin-silver-zinc, tin-bismuth-indium, tin-zinc-indium, or tin-silver-antimony.

The chip stacked structure 20 in the stacked package structure includes a plurality of first semiconductor chips 201 stacked in sequence along a direction perpendicular to the upper surface of the first substrate 101, and the number of the first semiconductor chips 201 may be two, three, four, or more. In FIG. 2, an explanation is provided by taking the case where the chip stacked structure 20 has in it four first semiconductor chips 201 as an example.

The functions of the plurality of first semiconductor chips 201 in the chip stacked structure 20 are the same or different. In one embodiment, when the functions of the plurality of first semiconductor chips 201 are the same, the internal structures of the plurality of first semiconductor chips 201 are the same. In another embodiment, when the functions of the plurality of first semiconductor chips 201 are the same, the internal structures of the plurality of first semiconductor chips 201 are different.

According to different functions, the first semiconductor chips 201 may include logic chips and/or memory chips. In one embodiment, the logic chips may include but are not limited to gate arrays, unit substrate arrays, embedded arrays, structured application specific integrated circuits (ASICs), field programmable gate arrays (FPGAs), complex programmable logic devices (CPLDs), graphics processing units (GPUs), central processing units (CPUs), microprocessing units (MPUs), microcontroller units (MCUs), logic integrated circuits (ICs), disclosure processors (APs), display driver ICs (DDIs), radio frequency (RF) chips, power chips, or complementary metal oxide semiconductor (CMOS) image sensor. In one embodiment, the memory chips may include but are not limited to dynamic random access memories (DRAMs), static random-access memories (SRAMs), magnetoresistive random access memories (MRAMs), phase-change memories (PRAMs), resistive random access memories (RRAMs), or non-volatile memory chips (e.g., Flash).

In one embodiment, the functions of all first semiconductor chips 201 in the chip stacked structure 20 are the same. In some embodiments, all first semiconductor chips 201 in the chip stacked structure 20 are memory chips, for example, all the four first semiconductor chips 201 in the chip stacked structure 20 shown in FIG. 2 are memory chips. In another embodiment, all the first semiconductor chips 201 in the chip stacked structure 20 may also be logic chips.

In another embodiment, the functions of a part of the first semiconductor chips 201 in the chip stacked structure 20 are different from the functions of other part of the first semiconductor chips 201. In some embodiments, one or two first semiconductor chips 201 located at the bottom layer of the chip stacked structure 20 are logic chips, and the other first semiconductor chips 201 located at the upper layer in the chip stack structure 20 are memory chips, and the logic chips are used to control and manage the data storage process, reading process (and deletion process) of the memory chips, for example, in FIG. 2, a first semiconductor chips 201 at the bottom layer in the chip stacked structure 20 is a logic chip, and three first semiconductor chips 201 located at the upper layer are memory chips.

There are electrical connections between the first semiconductor chips 201 in the upper layer and the first semiconductor chips 201 in the lower layer in the chip stacked structure 20, and there is an electrical connection between a first semiconductor chip 201 in the bottommost layer in the chip stacked structure 20 and the first substrate 101. In one embodiment, each first semiconductor chip 201 in the chip stacked structure includes opposed first surface and second surface, and a first side surface between the first surface and the second surface, and the first semiconductor chips 201 have in them integrated circuits, the integrated circuits may be memory circuits or logic control circuits, and the first surface has a plurality of discrete first external terminals, and the first external terminals may be solder balls 205 or solder balls 206 protruding from the first surface, and the second surface has a plurality of discrete second external terminals, and the second external terminals may be through-via connection structures 207 (e.g., through-silicon-vias, TSVs) exposed on the second surface, and the first external terminals and the second external terminals are electrically connected with the integrated circuits; when the plurality of first semiconductor chips 201 are stacked in sequence along a direction perpendicular to the upper surface of the first substrate, the first surfaces of the first semiconductor chips 201 in the upper layer are stacked facing downward on the second surface of the first semiconductor chips 201 in the lower layer, and the first external terminals on the first surfaces of the first semiconductor chips 201 in the upper layer are electrically connected with the second external terminals on the second surfaces of the first semiconductor chips 201 in the lower layer. In some embodiments, the solder balls 205 on the first surfaces of the first semiconductor chips 201 in the upper layer are electrically connected with the through-via connection structures 207 exposed on the second surfaces of the first semiconductor chips 201 in the lower layer, and the solder balls 206 (the first external terminals) on the first surface of a first semiconductor chip 201 at the bottommost layer in the chip stacked structure 20 are electrically connected with the corresponding first upper solder pads on the upper surface of the first substrate 101, and the solder balls 205 are small-sized micro solder balls, and the solder balls 206 may be relatively larger C4 solder balls.

Referring again to FIGS. 1 and 2, the first flexible circuit board 111 in the stacked package structure is also known as a soft board or a flexible printed circuit (FPC), and the first flexible circuit board 111 not only can be used for electrically connecting the chip stacked structure 20 from the top surface with the second flexible circuit board 112 arranged on one side of or periphery of the chip stacked structure 20, and the first flexible circuit board 111 but also can be used for interconnections between a part of the second external terminals on the second surfaces of the first semiconductor chips 201 of the topmost layer in the chip stacked structure 20. In one embodiment, the first flexible circuit board 111 includes opposed first functional surface and second functional surface, and the first flexible circuit board 111 further includes a first portion and at least one second portion connected with the first portion, and the first flexible circuit board 111 has in its second lines (not shown in the figures), and the first functional surfaces of the first portion and the second portion of the first flexible circuit board 111 have a plurality of discrete first solder pads (not shown in the figures), and the second functional surface of the second portion of the first flexible circuit board 111 has a plurality of discrete second solder pads (not shown in the figures), and the first solder pads and the second solder pads are electrically connected with the first lines. The first functional surface of the first portion of the first flexible circuit board 111 is mounted on the top surface of the chip stacked structure 20, and the first solder pads of the first portion are electrically connected with the chip stacked structure 20, and the second portion of the first flexible circuit board 111 is bent to the side surface of the chip stacked structure 20, and the second solder pads on the second functional surface of the second portion can be electrically connected with the second flexible circuit board 112.

In one embodiment, the first functional surface of the first portion of the first flexible circuit board 111 being mounted on the top surface of the chip stacked structure 20 and electrically connected with the chip stacked structure 20 includes: the first solder pads on the first functional surface of the first portion of the first flexible circuit board 111 are soldered together with corresponding second external terminals on the second surfaces of the first semiconductor chips 201 of the topmost layer in the chip stacked structure 20 through first solder bumps 113. The material of the first solder bumps 113 may be tin or tin alloy.

In one embodiment, when the second portion of the first flexible circuit board 111 is bent to the side surface of the chip stacked structure 20, the first functional surface and the second functional surface of the second portion of the first flexible circuit board 111 are non-parallel to the upper surface of the first substrate 101, in some embodiments, the first functional surface and the second functional surface of the second portion of the first flexible circuit board 111 may be perpendicular to the upper surface of the first substrate 101, or form an angle less than 90 degrees with the upper surface of the first substrate 101, thereby reducing the horizontal area occupied on the upper surface of the first substrate 100.

The second flexible circuit board 112 is also known as a soft board or a flexible printed circuit (FPC), and the second flexible circuit board 112 not only can be used for electrical connections of the first flexible circuit board 111 with the second semiconductor chips 202, and the second flexible circuit board 112 but also can be used for electrical connections between different external terminals on the second semiconductor chips 202. In one embodiment, the second flexible circuit board 112 includes opposed third functional surface and fourth functional surface, and a part of the third functional surface of the second flexible circuit board 112 is mounted on the second functional surface of the second portion of the first flexible circuit board 111 and is electrically connected with the first flexible circuit board 111. When the second flexible circuit board 112 is mounted on the second functional surface of the second portion of the first flexible circuit board 111, the third functional surface and the fourth functional surface of the second flexible circuit board 112 are non-parallel to the upper surface of the first substrate 101, in some embodiments, the third functional surface and the fourth functional surface of the second flexible circuit board 112 may be perpendicular to the upper surface of the first substrate 101, or form an angle less than 90 degrees with the upper surface of the first substrate 101, thereby reducing the horizontal area occupied on the upper surface of the first substrate 100. In one embodiment, the second flexible circuit board 212 has in its third lines (not shown in the figures), and the third functional surface of the second flexible circuit board 212 has a plurality of discrete third solder pads (not shown in the figures), and the fourth functional surface of the second flexible circuit board 212 has a plurality of discrete fourth solder pads (not shown in the figures), and the third solder pads and the fourth solder pads are electrically connected with the third lines.

In one embodiment, a part of the third functional surface of the second flexible circuit board 112 being mounted on the second functional surface of the second portion of the first flexible circuit board 111 and electrically connected with the first flexible circuit board 111 includes: the third solder pads on a part of the third functional surface of the second flexible circuit board 112 are soldered together with corresponding second solder pads on the second functional surface of the second portion of the first flexible circuit board 111 through second solder bumps 114.

On the fourth functional surface of the second flexible circuit board 112, second semiconductor chips are mounted and electrically connected with it, and the functional surfaces of the second semiconductor chips 202 (the surface formed with external terminals and opposed to the fourth functional surface of the second flexible circuit board 112) are also non-parallel to the upper surface of the first substrate 101, in some embodiments, the functional surfaces of the second semiconductor chips 202 may be perpendicular to the upper surface of the first substrate 101, or form an angle less than 90 degrees with the upper surface of the first substrate 101. Thus, in the stacked package structure of the present disclosure, the first flexible circuit board 111, the second flexible circuit board 112, and the second semiconductor chips 202 have the aforementioned specific mounting positions, and the first functional surface and the second functional surface of the second portion of the first flexible circuit board 111 are non-parallel to the upper surface of the first substrate 101, and the third functional surface and the fourth functional surface of the second flexible circuit board 112 are non-parallel to the upper surface of the first substrate 101, and the functional surfaces of the second semiconductor chips 202 are also non-parallel to the upper surface of the first substrate 101, such that the areas occupied by the first flexible circuit board 111, the second flexible circuit board 112, and the second semiconductor chips 202 on the upper surface of the first substrate 101 will be smaller, and thus more other chips or devices can be mounted on the upper surface of the first substrate 101, which further improves the functionality and performance of the package structure; moreover, the presence of the first flexible circuit board 111 and the second flexible circuit board 112 increases the connection pathways between the chip stacked structure 20 and external substrates or devices, which, on the one hand, can increase bandwidth (the chip stacked structure 20 not only can be directly electrically connected with the first substrate 101 but also can be electrically connected with the first substrate 101 and the second semiconductor chips 202 and/or the subsequently introduced third semiconductor chips through the first flexible circuit board 111 and the second flexible circuit board 112), and which, on the other hand, can achieve more functional expansion and performance improvement of the package structure while occupying a smaller area on the upper surface of the first substrate 101 (e.g., a second semiconductor chip 202 with specific functions can be mounted or a plurality of second semiconductor chips 202 with the same or different functions can be mounted on the fourth functional surface of the second flexible circuit board 112, a third semiconductor chip with specific functions can be mounted or a plurality of third semiconductor chips with the same or different functions can be mounted on the first functional surface of the second portion of the first flexible circuit board 111).

The second semiconductor chips 202 may have different functions from the first semiconductor chips 201 in the chip stacked structure 20, or may have the same functions. In one embodiment, the second semiconductor chips 202 may be logic chips or memory chips. In one embodiment, the second semiconductor chips 202 being mounted on the fourth functional surface of the second flexible circuit board 112 and electrically connected with the second flexible circuit board 112 includes: the second semiconductor chips 202 are soldered together with the corresponding fourth solder pads on the fourth functional surface of the second flexible circuit board 112 through third solder bumps 212. The material of the third solder bumps 212 may be tin or tin alloy.

The number of the second semiconductor chips 202 is one or more. In one embodiment, when the number of second semiconductor chips 202 is multiple, the multiple second semiconductor chips 202 are stacked in sequence on the fourth functional surface of the second flexible circuit board 112 along a direction parallel to the upper surface of the first substrate 100, or the multiple second semiconductor chips 202 are all mounted at different positions on the fourth functional surface of the second flexible circuit board 112.

Referring again to FIGS. 1 and 2, the chip stacked structure 20 includes opposed top surface and bottom surface, as well as a plurality of side surfaces located between the top surface and the bottom surface, in one embodiment, the chip stacked structure 20 is a cubic structure, the chip stacked structure 20 may include a top surface, a bottom surface, as well as four side surfaces located between the top surface and the bottom surface, the first surfaces of the first semiconductor chips 201 at the bottom layer of the chip stacked structure 20 correspond to the bottom surface, and the second surfaces of the first semiconductor chips 201 at the top layer of the chip stacked structure 20 correspond to the top surface.

The number of the second portions in the first flexible circuit board 111 is one or more. In one embodiment, when the second portion is multiple, the multiple second portions are all electrically connected with the first portion, and the number of the second portions may correspond to the number of side surfaces of the chip stacked structure 20 (e.g., when the side surfaces of the chip stacked structure 20 are four, the number of the multiple second portions may be two, three, or four), and the multiple second portions are bent to different side surfaces of the chip stacked structure 20, respectively. In one example, as shown in FIG. 1, the chip stacked structure 20 has four side surfaces, the second portions of the first flexible circuit board 111 are four, and the four second portions are connected with the first portion from four sides of the first portion of the first flexible circuit board 111, and the four second portions are bent to the four sides of the chip stacked structure 20, respectively.

The number of second flexible circuit boards 112 is one or more. In one embodiment, when the number of second flexible circuit boards 112 is one, the one second flexible circuit board 112 is electrically connected with one or more of the second portions of the first flexible circuit board 111. In another embodiment, when the number of second flexible circuit boards 112 is multiple, the multiple second flexible circuit boards 112 are correspondingly electrically connected with the plurality of second portions of the first flexible circuit board 111, respectively. The second flexible circuit board 112 and the first flexible circuit board 111 can be arranged outside each of the plurality of side surfaces (which may be two, three, or four side surfaces, or all side surfaces) of the chip stacked structure 20, which increases the arrangeable surface area of the second flexible circuit board 112 and the first flexible circuit board 111, so that, in the case of occupying a smaller area of the upper surface of the first substrate 101, the second flexible circuit board 112 and the first flexible circuit board 111 can not only provide more conductive paths to further increase bandwidth, and more second semiconductor chips 202 can be mounted on the fourth functional surface of the second flexible circuit board 112, and more third semiconductor chips can be mounted on the first functional surface of the second portion of the first flexible circuit board 111 to further expand the functionality of the stacked package structure and improve the performance of the stacked package structure.

The second functional surface of the second portion of the first flexible circuit board 111 is adhered to the side surface of the chip stacked structure 20. In one embodiment, referring again to FIGS. 1 and 2, the second functional surface of the second portion of the first flexible circuit board 111 is directly adhered to the side surface of the chip stacked structure through an adhesive layer 106.

In one embodiment, the stacked package structure further includes other semiconductor chips or devices 204, the other semiconductor chips or devices 204 are mounted on the upper surface of the first substrate 101 on one side of the chip stacked structure 20, in some embodiments, the external terminals of the semiconductor chips or devices 204 are electrically connected with the upper surface of the first substrate 101 through sixth solder bumps 214. The other semiconductor chips or devices 204 may be electrically connected with the chip stacked structure 20 through a part of the first lines in the first substrate 101 to communicate or exchange or transmit data, for example, they are electrically connected with one first semiconductor chip 201 of the bottom layer in the chip stacked structure 20. In some embodiments, the other semiconductor chips or devices 204 may also be electrically connected with the second semiconductor chips 202 through a part of the first lines in the first substrate 101 and a part of the third lines in the second flexible circuit board 112 to communicate or exchange or transmit data. In some embodiments, the other semiconductor chips or devices 204 may also be simultaneously electrically connected with the chip stacked structure 20 and the second semiconductor chips 202 through a part of the first lines in the first substrate 101 and a part of the third lines in the second flexible circuit board 112 to communicate or exchange or transmit data.

The second flexible circuit board 112 may be electrically connected with or may not be electrically connected with the first substrate 101. In one embodiment, referring again to FIGS. 1 and 2, when the second flexible circuit board 112 may not be electrically connected with the first substrate 101, a side surface of the second flexible circuit board 112 close to the upper surface of the first substrate 101 may be suspended above the upper surface of the first substrate 101, directly located on the upper surface of the first substrate 101, or adhered on the upper surface of the first substrate 101 through an adhesive layer. The specific circumstances under which the second flexible circuit board 112 may not be electrically connected with the first substrate 101 will be described in detail in subsequent embodiments.

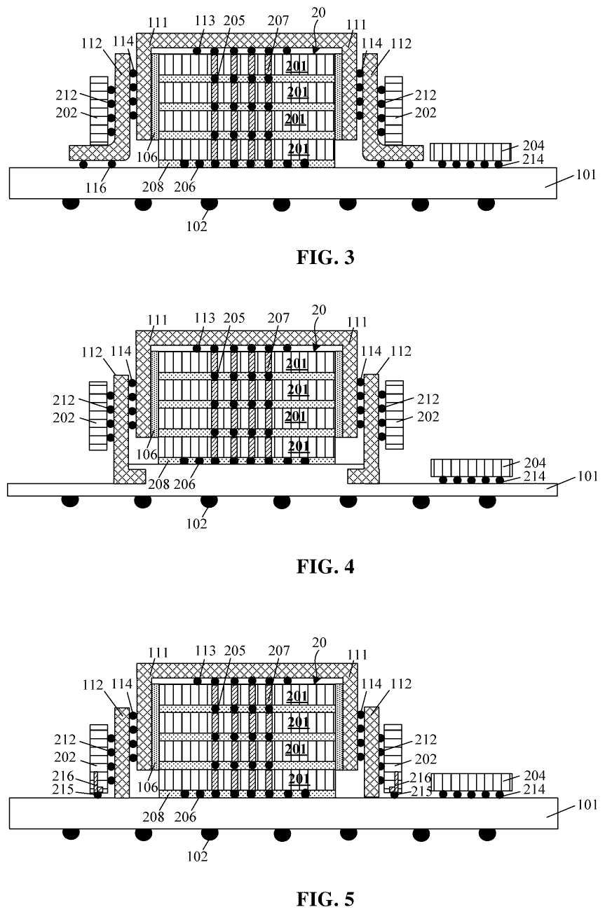

Another embodiment of the present disclosure also provides a stacked package structure, referring to FIGS. 1 and 3, the difference between the present embodiment and the aforementioned embodiments lies in: the second flexible circuit board 112 is electrically connected with the first substrate 101, the method of this electrical connection is: a part of the second flexible circuit board 112 is bent and extends parallel to a part of the upper surface of the first substrate 101, and the bent portion of the second flexible circuit board 112 is soldered and electrically connected with the corresponding first upper solder pads on the upper surface of the first substrate 101 through connecting solder balls 116.

Yet another embodiment of the present disclosure provides a stacked package structure, referring to FIGS. 1 and 4, the difference between the present embodiment and the aforementioned embodiments lies in: the second flexible circuit board 112 is electrically connected with the first substrate 101, and the method of this electrical connection is: the second flexible circuit board 112 and the first substrate 101 are rigid-flex boards, and the second flexible circuit board 112 is flexible and the first substrate 101 is rigid, and the second flexible circuit board 112 is partially embedded into the first substrate 101 to achieve electrical connection with the first substrate 101, in some embodiments, one end of the second flexible circuit board 112 is embedded into the first substrate 101 to be electrically connected with the first substrate 101. When the second flexible circuit board 112 and the first substrate 101 are rigid-flex boards, the second flexible circuit board 112 and the first substrate 101 may be manufactured together, the connection precision between the second flexible circuit board 112 and the first substrate 101 is improved, and since one end of the second flexible circuit board 112 is fixed in the first substrate 101, the difficulty of mounting the second flexible circuit board 112 is reduced, and the mounting precision is improved; moreover, the connection between the second flexible circuit board 112 and the first substrate 101 does not require solder bumps, which enhances the signal transmission rate between the second flexible circuit board 112 and the first substrate 101.

Yet another embodiment of the present disclosure provides a stacked package structure, referring to FIGS. 1 and 5, the difference between the present embodiment and the aforementioned embodiments lies in: the second semiconductor chips 202 include opposed third surface and fourth surface and a plurality of side surfaces between the third surface and the fourth surface, and the third surface has third external terminals, and the third external terminals on the third surfaces of the second semiconductor chips 202 are electrically connected with the corresponding fourth solder pads on the fourth functional surface of the second flexible circuit board 112 through third solder bumps 212; the side surfaces of the second semiconductor chips 202 close to the upper surface of the first substrate have side solder pads 216, the side solder pads 216 are soldered together with the corresponding first upper solder pads on the upper surface of the first substrate 101 through fifth solder bumps 215.

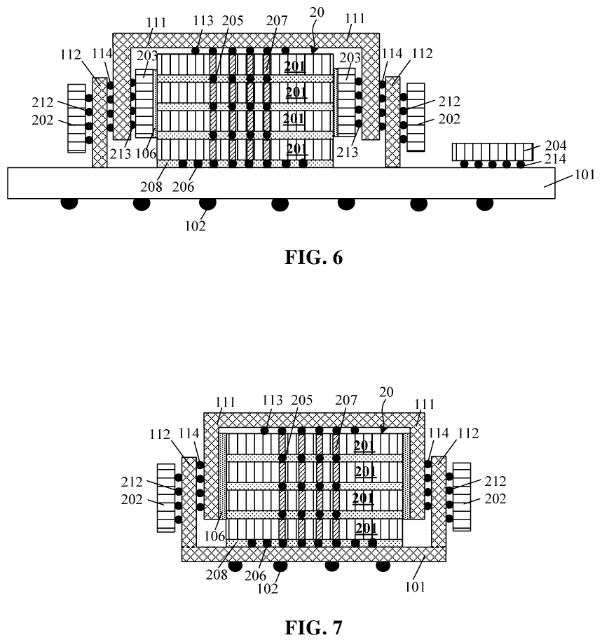

Yet another embodiment of the present disclosure provides a stacked package structure, referring to FIGS. 1 and 6, the difference between the present embodiment and the aforementioned embodiments lies in: the second flexible circuit board 112 may or may not be electrically connected with the first substrate 101, and the stacked package structure further includes third semiconductor chips 203, and the third semiconductor chips 203 are mounted on the first functional surface of the second portion of the first flexible circuit board 111 and are electrically connected with the corresponding first solder pads on the first functional surface of the second portion of the first flexible circuit board 111 through fourth solder bumps 213; the surfaces of the third semiconductor chips 203 away from the first functional surface of the second portion of the first flexible circuit board 111 are directly adhered to the side surface of the chip stacked structure 20 through an adhesive layer 106. The third semiconductor chips 203 mounted in this manner occupy a smaller horizontal area on the first substrate 101, thereby achieving further expansion with more functions and further improvement of performance of the package structure while occupying a smaller surface area on the upper surface of the first substrate 101. The second semiconductor chips 202 may have different functions from the first semiconductor chips 201 in the chip stacked structure 20, or they may have the same functions. In one embodiment, the second semiconductor chips 202 may be logic chips or memory chips.

Yet another embodiment of the present disclosure further provides a stacked package structure, referring to FIGS. 1 and 7, the difference between the present embodiment and the aforementioned embodiments lies in: the second flexible circuit board 112 is electrically connected with the first substrate 101, and the method of this electrical connection is: the first substrate 101 is also a flexible board, and the first substrate 101 and the second flexible circuit board 112 are a one-piece structure with an electrical connection, and the second flexible circuit board 112 is bent upward from at least one side of the first substrate 101. In some embodiments, the first substrate 101 includes four sides, and the second flexible circuit board 112 is bent upward from one of the sides of the first substrate 101, or the second flexible circuit board 112 is bent upward from two of the sides of the first substrate 101, or the second flexible circuit board 112 is bent upward from three of the sides of the first substrate 101, or the second flexible circuit board 112 is bent upward from four of the sides of the first substrate 101.

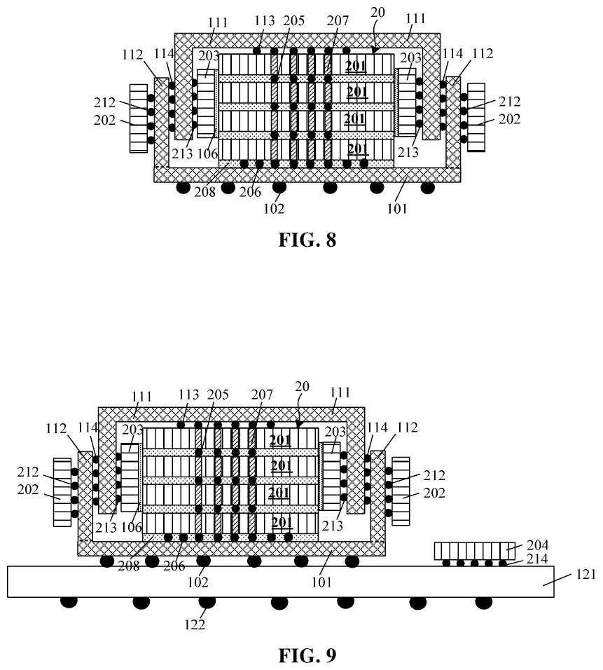

Yet another embodiment of the present disclosure further provides a stacked package structure, referring to FIGS. 1 and 8, the difference between the present embodiment and the aforementioned embodiments lies in: the second flexible circuit board 112 is electrically connected with the first substrate 101, and the method of this electrical connection is: the first substrate 101 is also a flexible board, and the first substrate 101 and the second flexible circuit board 112 are a one-piece structure with an electrical connection, and the second flexible circuit board 112 is bent upward from at least one side of the first substrate 101; the third semiconductor chips 203 are mounted on the first functional surface of the second portion of the first flexible circuit board 111 and are electrically connected with the corresponding first solder pads on the first functional surface of the second portion of the first flexible circuit board 111 through the fourth solder bumps 213; the surfaces of the third semiconductor chips 203 away from the first functional surface of the second portion of the first flexible circuit board 111 are directly adhered to the side surface of the chip stacked structure 20 through an adhesive layer 106.

Yet another embodiment of the present disclosure further provides a stacked package structure, referring to FIGS. 1 and 9, the difference between the present embodiment and the aforementioned embodiments lies in: the second flexible circuit board 112 is electrically connected with the first substrate 101, and the method of this electrical connection is: the first substrate 101 is also a flexible board, and the first substrate 101 and the second flexible circuit board 112 are a one-piece structure with an electrical connection, and the surfaces of the first lower solder pads on the lower surface of the first substrate 101 have protruding first external solder bumps 102; the stacked package structure further includes: a second substrate 121, and the second substrate 121 has in its fourth lines, the upper surface of the second substrate has second upper solder pads, and the lower surface of the second substrate 121 has second lower solder pads, and the second upper solder pads and the second lower solder pads are electrically connected with the fourth lines; the first substrate 101 is located on the second substrate 121, and the first external solder bumps 102 on the lower surface of the first substrate 101 are soldered together with the corresponding second upper solder pads on the upper surface of the second substrate 121; the surfaces of the second lower solder pads on the lower surface of the second substrate 121 have protruding second external solder bumps 122. The other semiconductor chips or devices 204 are mounted on the upper surface of the second substrate 121 and are electrically connected with the second substrate 121.

Yet another embodiment of the present disclosure further provides a stacked package structure, the difference between the present embodiment and the aforementioned embodiments lies in: the second flexible circuit board 112 is electrically connected with the first substrate 101, and the method of this electrical connection is: the first substrate further includes a plurality of side surfaces located between the upper surface and the lower surface, and the second flexible circuit board extends from at least one side surface of the first substrate to the lower surface of the first substrate and is electrically connected with the first substrate from the lower surface of the first substrate.

In another aspect, the embodiments of the present disclosure further provide a method for forming a stacked package structure. In one embodiment, referring to FIG. 1, the method for forming the stacked package structure includes: providing a first substrate 101, the first substrate 101 includes opposed upper surface and lower surface; forming a chip stacked structure 20 on the upper surface of the first substrate 101, the chip stacked structure 20 includes a plurality of first semiconductor chips 201 stacked in sequence along a direction perpendicular to the upper surface of the first substrate 101, and the chip stacked structure 20 is electrically connected with the first substrate 101; providing a first flexible circuit board 111, the first flexible circuit board 111 includes opposed first functional surface and second functional surface, and the first flexible circuit board 111 includes a first portion and at least one second portion connected with the first portion, the first functional surface of the first portion of the first flexible circuit board 111 is mounted on the top surface of the chip stacked structure 20 and is electrically connected with the chip stacked structure 20, and the second portion of the first flexible circuit board 111 is bent to the side surface of the chip stacked structure 20; providing a second flexible circuit board 112, the second flexible circuit board 112 includes opposed third functional surface and fourth functional surface, and a part of the third functional surface of the second flexible circuit board 112 is mounted on the second functional surface of the second portion of the first flexible circuit board 111 and is electrically connected with the first flexible circuit board 111; and providing second semiconductor chips 202, the second semiconductor chips 202 are mounted on the fourth functional surface of the second flexible circuit board 112 and are electrically connected with the second flexible circuit board 112.

In one embodiment, each first semiconductor chip 201 in the chip stacked structure 20 includes opposed first surface and second surface, and a first side surface located between the first surface and the second surface, and the first semiconductor chips 201 have in them integrated circuits, and the first surface has a plurality of discrete first external terminals, and the second surface has a plurality of discrete second external terminals, and the first external terminals and second external terminals are electrically connected with the integrated circuits; when the plurality of first semiconductor chips 201 are stacked in sequence along a direction perpendicular to the upper surface of the first substrate 101, the first surfaces of the first semiconductor chips 201 in the upper-layer are stacked facing downward on the second surfaces of the first semiconductor chips 201 in the lower-layer, and the first external terminals on the first surfaces of the first semiconductor chips 201 in the upper-layer are electrically connected with the second external terminals on the second surfaces of the first semiconductor chips 201 in the lower-layer; the first substrate 101 has in it first lines, and the upper surface of the first substrate 101 has a plurality of discrete first upper solder pads, and the lower surface of the first substrate 101 has a plurality of discrete first lower solder pads, and the first upper solder pads and first lower solder pads are electrically connected with the first lines, the first external terminals on the first surfaces of the first semiconductor chips 201 of the bottommost layer are electrically connected with the corresponding first upper solder pads on the upper surface of the first substrate 101.

In one embodiment, the first flexible circuit board 111 has in its second lines; the first functional surfaces of the first portion and the second portion of the first flexible circuit board 111 have a plurality of discrete first solder pads, the second functional surface of the second portion of the first flexible circuit board 111 has a plurality of discrete second solder pads, and the first solder pads and the second solder pads are electrically connected with the first lines; the first flexible circuit board 112 has in its third lines, and the third functional surface of the first flexible circuit board 112 has a plurality of discrete third solder pads, and the fourth functional surface of the first flexible circuit board 112 has a plurality of discrete fourth solder pads, and the third solder pads and the fourth solder pads are electrically connected with the third lines; the first functional surface of the first portion of the first flexible circuit board 111 being mounted on the top surface of the chip stacked structure 20 and electrically connected with the chip stacked structure 20 includes: the first solder pads on the first functional surface of the first portion of the first flexible circuit board 111 are soldered together with the corresponding second external terminals on the second surfaces of the first semiconductor chips 201 of the topmost layer in the chip stacked structure 20 through first solder bumps 113; a part of the third functional surface of the second flexible circuit board 112 being mounted on the second functional surface of the second portion of the first flexible circuit board 111 and electrically connected with the first flexible circuit board 111 includes: third solder pads on a part of the third functional surface of the second flexible circuit board 112 are soldered together with corresponding second solder pads on the second functional surface of the second portion of the first flexible circuit board 111 through second solder bumps 114; and the second semiconductor chips being mounted on the fourth functional surface of the second flexible circuit board 112 and electrically connected with the second flexible circuit board 112 includes: the second semiconductor chips 202 are soldered together with the corresponding fourth solder pads on the fourth functional surface of the second flexible circuit board 112 board through third solder bumps 212.

In one embodiment, the formation method further includes: the second functional surface of the second portion of the first flexible circuit board 111 is adhered to the side surface of the chip stacked structure 20.

In one embodiment, the second functional surface of the second portion of the first flexible circuit board 111 is directly adhered to the side surface of the chip stacked structure 20 through an adhesive layer 106 (referring to any one of FIGS. 2-5).

In one embodiment, referring to FIG. 6 or FIG. 8, the forming method further includes: providing third semiconductor chips 203, the third semiconductor chips 203 are mounted on the first functional surface of the second portion of the first flexible circuit board 111 and are electrically connected with the corresponding first solder pads on the first functional surface of the second portion through fourth solder bumps 213; the surfaces of the third semiconductor chips 203 away from the first functional surface of the second portion of the first flexible circuit board 111 are directly adhered to the side surface of the chip stacked structure 20 through an adhesive layer 106.

It should be noted that the same or similar parts between the embodiments of the aforementioned method for forming the stacked package structure and the embodiments of the aforementioned stacked package structure will not be repeated in the embodiment portions of the method for forming the stacked package structure, and for details, reference may be made to the definitions or descriptions of the corresponding sections in the embodiments of the aforementioned stacked package structure.

Although the present disclosure has been disclosed above with the embodiments, they are not intended to limit the present disclosure; any person skilled in the art may make possible changes and modifications to the technical solutions disclosed herein without departing from the spirit and scope of the present disclosure, therefore, any simple modifications, equivalent changes, and refinements made to the above embodiments based on the technical essence of the present disclosure without departing from the content of the technical solutions of the present disclosure, shall fall within the scope of protection of the technical solutions of the present disclosure.

What is claimed is:

1. A stacked package structure, comprising:
a first substrate comprising: an upper surface, and a lower surface opposite to the upper surface;
a chip stacked structure located on the upper surface of the first substrate, wherein the chip stacked structure comprises: a plurality of first semiconductor chips stacked in sequence along a direction perpendicular to the upper surface of the first substrate, and the chip stacked structure is electrically connected with the first substrate;
a first flexible circuit board comprising: a first functional surface; and a second functional surface opposite to the first functional surface, wherein the first flexible circuit board further comprises: a first portion; and at least one second portion connected to the first portion, wherein the first functional surface of the first portion of the first flexible circuit board is mounted on a top surface of the chip stacked structure and is electrically connected to the chip stacked structure, and the second portion of the first flexible circuit board is bent to a side surface of the chip stacked structure;
a second flexible circuit board comprising: a third functional surface; and a fourth functional surface opposite to the third functional surface, wherein a part of the third functional surface of the second flexible circuit board is mounted on the second functional surface of the second portion of the first flexible circuit board and is electrically connected to the first flexible circuit board; and
second semiconductor chips mounted on the fourth functional surface of the second flexible circuit board and electrically connected to the second flexible circuit board.

2. The stacked package structure according to claim 1, wherein:
each of the first semiconductor chips in the chip stacked structure comprises: a first surface, a second surface opposite to the first surface, and a first side surface located between the first surface and the second surface;
the first semiconductor chips comprise integrated circuits, the first surface comprises a plurality of discrete first external terminals, the second surface comprises a plurality of discrete second external terminals, and the first external terminals and second external terminals are electrically connected to the integrated circuits;
when the plurality of first semiconductor chips are stacked in sequence along the direction perpendicular to the upper surface of the first substrate, the first surface of an upper-layer first semiconductor chip is stacked facing downward on the second surface of a lower-layer first semiconductor chip, and the first external terminals on the first surface of the upper-layer first semiconductor chip are electrically connected to the second external terminals on the second surface of the lower-layer first semiconductor chip; and
the first substrate comprises first lines, the upper surface of the first substrate comprises a plurality of discrete first upper solder pads, the lower surface of the first substrate comprises a plurality of discrete first lower solder pads, the first upper solder pads and the first lower solder pads are electrically connected to the first lines, the first external terminals on the first surface of a bottommost first semiconductor chip are electrically connected to the corresponding first upper solder pads on the upper surface of the first substrate.

3. The stacked package structure according to claim 2, wherein:
the first flexible circuit board comprises second lines;
the first functional surface of the first portion and the first functional surface of the at least one second portion of the first flexible circuit board each comprise a plurality of discrete first solder pads;
the second functional surface of the at least one second portion of the first flexible circuit board comprises a plurality of discrete second solder pads;
the first solder pads and the second solder pads are electrically connected to the first lines;
the second flexible circuit board comprises third lines;
the third functional surface of the second flexible circuit board comprises a plurality of discrete third solder pads;
the fourth functional surface of the second flexible circuit board comprises a plurality of discrete fourth solder pads; and
the third solder pads and the fourth solder pads are electrically connected to the third lines.

4. The stacked package structure according to claim 3, wherein:
the first functional surface of the first portion of the first flexible circuit board is mounted on and electrically connected to the top surface of the chip stacked structure comprises: the first solder pads on the first functional surface of the first portion are soldered to corresponding second external terminals on the second surface of a topmost first semiconductor chip in the chip stacked structure via first solder bumps;
a part of the third functional surface of the second flexible circuit board is mounted on and electrically connected to the second functional surface of the second portion of the first flexible circuit board comprises: the third solder pads on the part of the third functional surface are soldered to corresponding second solder pads on the second functional surface of the second portion via second solder bumps; and
the second semiconductor chips are mounted on and electrically connected to the fourth functional surface of the second flexible circuit board comprises: the second semiconductor chips are soldered to corresponding fourth solder pads on the fourth functional surface via third solder bumps.

5. The stacked package structure according to claim 3, wherein the second functional surface of the second portion of the first flexible circuit board is adhered to the side surface of the chip stacked structure.

6. The stacked package structure according to claim 5, wherein the second functional surface of the second portion of the first flexible circuit board is directly adhered to the side surface of the chip stacked structure through an adhesive layer.

7. The stacked package structure according to claim 5, further comprising:
one or more third semiconductor chips mounted on the first functional surface of the second portion of the first flexible circuit board and electrically connected to corresponding first solder pads on the first functional surface of the second portion through fourth solder bumps,
wherein surfaces of the one or more third semiconductor chips facing away from the first functional surface of the second portion of the first flexible circuit board are directly adhered to the side surface of the chip stacked structure through an adhesive layer.

8. The stacked package structure according to claim 1, wherein the second flexible circuit board is not electrically connected to the first substrate.

9. The stacked package structure according to claim 1, wherein the second flexible circuit board is electrically connected to the first substrate.

10. The stacked package structure according to claim 9, wherein the second flexible circuit board is electrically connected to the first substrate comprises:
a part of the second flexible circuit board is bent and extends parallel to a part of the upper surface of the first substrate; and
a bent portion of the second flexible circuit board is soldered and electrically connected to corresponding first upper solder pads on the upper surface of the first substrate through connection solder balls.

11. The stacked package structure according to claim 9, wherein:
the second flexible circuit board is electrically connected to the first substrate comprises: the second flexible circuit board and the first substrate are rigid-flex boards, the second flexible circuit board is flexible and the first substrate is rigid, and the second flexible circuit board is partially embedded into the first substrate and electrically connected to the first substrate.

12. The stacked package structure according to claim 9, wherein:
the second flexible circuit board is electrically connected to the first substrate comprises: the first substrate further comprises a plurality of side surfaces located between the upper surface and the lower surface; and
the second flexible circuit board extends from at least one side surface of the first substrate to the lower surface of the first substrate and is electrically connected to the first substrate from the lower surface of the first substrate.

13. The stacked package structure according to claim 9, wherein:
the second flexible circuit board is electrically connected to the first substrate comprises: the first substrate is also a flexible board, and each of the first substrate and the second flexible circuit board is a one-piece structure with an electrical connection; and
the second flexible circuit board is bent upward from at least one side of the first substrate.

14. The stacked package structure according to claim 13, wherein:
surfaces of first lower solder pads on the lower surface of the first substrate comprise protruding first external solder bumps;
the stacked package structure further comprises: a second substrate comprising fourth lines;
an upper surface of the second substrate comprises second upper solder pads;
a lower surface of the second substrate comprises second lower solder pads;
the second upper solder pads and the second lower solder pads are electrically connected to the fourth lines;
the first substrate is located on the second substrate;
the first external solder bumps on the lower surface of the first substrate are soldered to the corresponding second upper solder pads on the upper surface of the second substrate; and
surfaces of the second lower solder pads on the lower surface of the second substrate comprise protruding second external solder bumps.

15. The stacked package structure according to claim 1, wherein:
a number of the at least one second portion of the first flexible circuit board is one or more; and
when there are a plurality of second portions, the plurality of second portions are respectively bent to different side surfaces of the chip stacked structure.

16. The stacked package structure according to claim 15, wherein:
a number of the second flexible circuit boards is one or more;
when the number of the second flexible circuit boards is one, the one second flexible circuit board is electrically connected to one or more of the second portions of the first flexible circuit board; and
when the number of the second flexible circuit boards is multiple, the multiple second flexible circuit boards are electrically connected to the plurality of corresponding second portions of the first flexible circuit board, respectively.

17. The stacked package structure according to claim 6, wherein:
a number of the second semiconductor chips is one or more;
when the number of the second semiconductor chips is multiple, the multiple second semiconductor chips are stacked in sequence along a direction parallel to the upper surface of the first substrate on the fourth functional surface of the second flexible circuit board, or
the multiple second semiconductor chips are all mounted at different positions on the fourth functional surface of the second flexible circuit board.

18. The stacked package structure according to claim 17, wherein:
the second semiconductor chips comprise: a third surface; a fourth surface opposite to the third surface; and a plurality of side surfaces between the third surface and the fourth surface;
the third surface comprises: third external terminals electrically connected to the corresponding fourth solder pads on the fourth functional surface of the second flexible circuit board through third solder bumps; and
a side surface of the second semiconductor chips close to the upper surface of the first substrate comprises side solder pads, and the side solder pads are soldered to corresponding first upper solder pads on the upper surface of the first substrate through fifth solder bumps.

19. A method for forming a stacked package structure, comprising:
providing a first substrate comprising an upper surface and a lower surface opposite to the upper surface;
forming a chip stacked structure on the upper surface of the first substrate, wherein the chip stacked structure comprises a plurality of first semiconductor chips stacked in sequence along a direction perpendicular to the upper surface of the first substrate, and the chip stacked structure is electrically connected to the first substrate;
providing a first flexible circuit board comprising a first functional surface and a second functional surface opposite to the first functional surface, wherein the first flexible circuit board comprises a first portion and at least one second portion connected to the first portion, the first functional surface of the first portion of the first flexible circuit board is mounted on a top surface of the chip stacked structure and is electrically connected to the chip stacked structure, and the second portion of the first flexible circuit board is bent to a side surface of the chip stacked structure;
providing a second flexible circuit board comprising a third functional surface and a fourth functional surface opposite to the third functional surface, wherein a part of the third functional surface of the second flexible circuit board is mounted on the second functional surface of the second portion of the first flexible circuit board and is electrically connected to the first flexible circuit board; and
providing second semiconductor chips, wherein the second semiconductor chips are mounted on the fourth functional surface of the second flexible circuit board and are electrically connected to the second flexible circuit board.

20. The method for forming a stacked package structure according to claim 19, wherein:
each first semiconductor chip in the chip stacked structure comprises a first surface, a second surface opposite to the first surface, and a first side surface located between the first surface and the second surface;
the first semiconductor chips comprise integrated circuits, the first surface comprises a plurality of discrete first external terminals, the second surface comprises a plurality of discrete second external terminals, and the first external terminals and the second external terminals are electrically connected to the integrated circuits;
when the plurality of first semiconductor chips are stacked in sequence along a direction perpendicular to the upper surface of the first substrate, the first surface of an upper-layer first semiconductor chip is stacked facing downward on the second surface of a lower-layer first semiconductor chip, and the first external terminals on the first surface of the upper-layer first semiconductor chip are electrically connected to the second external terminals on the second surface of the lower-layer first semiconductor chip;
the first substrate comprises first lines, the upper surface of the first substrate comprises a plurality of discrete first upper solder pads, the lower surface of the first substrate comprises a plurality of discrete first lower solder pads, and the first upper solder pads and the first lower solder pads are electrically connected to the first lines; and
the first external terminals on the first surfaces of a bottommost first semiconductor chip are electrically connected to the corresponding first upper solder pads on the upper surface of the first substrate.
